(19) United States
(12) Patent Application Publication
(10) Pub. No.: US 2022/0052721 A1
(43) Pub. Date: Feb. 17, 2022

(54) Broadcast Receiving Device of a Motor Vehicle

(71) Applicant: Bayerische Motoren Werke Aktiengesellschaft, Muenchen (DE)

(72) Inventors: Matthias STUETZ, Unterschleissheim (DE); Wolfram WINKLER, Ingolstadt (DE)

(21) Appl. No.: 17/276,755

(22) PCT Filed: Aug. 30, 2019
(86) PCT No.: PCT/DE2019/100784

§ 371 Date: Mar. 16, 2021

(30) Foreign Application Priority Data
Sep. 17, 2018 (DE) 10 2018 215 763.4

(51) Int. Cl. H04B 1/18; H03F 3/19; H03F 1/56

(52) U.S. Cl. CPC H04B 1/18; H03F 3/19; H03F 2200/387; H03F 2200/451; H03F 1/56

(57) ABSTRACT

A broadcast receiving device for a motor vehicle includes at least one antenna having a given antenna impedance, an antenna amplifier having a given amplifier impedance and a matching circuit which is configured to adapt the antenna impedance to the amplifier impedance. The broadcast receiving device is characterized in that the matching circuit is arranged outside of the amplifier core of the antenna amplifier.

### BACKGROUND AND SUMMARY OF THE INVENTION

The invention relates to a broadcast receiving device for a motor vehicle. The broadcast receiving device comprises at least one antenna having a given antenna impedance, an antenna amplifier having a given amplifier impedance, and a matching circuit which is configured to adapt the antenna impedance to the amplifier impedance.

It is necessary for a broadcast receiving device (hereinafter: receiving device) to be newly-adapted to each vehicle type, as different vehicle types have different antennae, each having respective antenna impedances. Adaptation is carried out by means of a matching circuit which is integrated in the antenna amplifier, such that a dedicated and appropriate antenna amplifier is provided for each vehicle type. This results in a plurality of different variants across all vehicle types, with a resulting encumberment to both logistics and storage. Moreover, on the grounds of statutory provisions, it is necessary for each variation of the receiving device to be newly-certified which, for a vehicle manufacturer having a wide range of different vehicle types, is highly time-consuming and economically cost-intensive.

The object of the invention is to provide a broadcast receiving device, which is functionally and/or structurally improved such that the complexity of development is reduced, and costs for logistics, storage and the certification of individual components of the broadcast receiving device can be maintained as low as possible. Moreover, a motor vehicle is provided, having a correspondingly improved receiving device for broadcast signals.

These objects are fulfilled by a broadcast receiving device and by a motor vehicle according to the features the independent claims. Advantageous configurations proceed from the dependent patent claims.

A broadcast receiving device for a motor vehicle is proposed, comprising at least one antenna having a given antenna impedance, an antenna amplifier having an amplifier core having a given amplifier impedance, and a matching circuit, which is configured to adapt the antenna impedance to the amplifier impedance. According to the invention, the matching circuit is arranged externally to the amplifier core of the antenna amplifier.

The arrangement of the matching circuit in the form of a separate component from the antenna amplifier permits the employment of an antenna amplifier core which is constituted of identical components, regardless of the antenna type incorporated in the receiving device. Accordingly, the antenna amplifier no longer comprises, as previously, a combination of an amplifier core and a specific matching circuit, but only an identical amplifier core for receiving devices of different types. The matching circuit, which is arranged externally to the amplifier core of the antenna amplifier, as an individual “component”, is adapted to the combination of the antenna and the antenna amplifier or amplifier core. A reduced complexity of certification is thus required for the provision of the receiving device. The development of new receiving devices can be accelerated, as it is only necessary to complete a one-off certification for the amplifier core, which can be configured in the form of a standard antenna amplifier. Costs for the adaptation of a receiving device to different vehicle types can be reduced.

The provision of a receiving device-specific matching circuit can be achieved in a simple manner, as the matching circuit comprises only passive components, particularly coils and capacitors.

One configuration of the invention is characterized in that the amplifier core is arranged in a housing, wherein the matching circuit is arranged externally to the housing of the amplifier core.

The matching circuit can be an integral constituent of a signal transmission structure, which connects the antenna to the antenna amplifier or to the amplifier core. The signal transmission structure comprises all those components which are employed between an antenna output and an input of the amplifier core for the purposes of signal transmission, such as e.g. lines, plug-in connections or similar.

In one variant, the matching circuit can be arranged on or in a carrier, on or in which the antenna is provided. The carrier can be a special antenna carrier. The carrier can also be a window pane of the vehicle, if the receiving device is incorporated in the vehicle. The components of the matching circuit can thus be printed onto the carrier using a conductive material of a specific conductivity. A conductive silver paste, for example, can be employed as a conductive material.

Components of the matching circuit can also be produced from a conductive foil by a subtractive process, e.g. by laser ablation, wherein the foil is flush-bonded to the carrier, or is arranged in the carrier.

According to another alternative, components of the matching circuit can be applied to the carrier in the form of discrete components, particularly by soldering.

According to a further alternative configuration, it is provided that the components of the matching circuit are applied in the form of discrete components to a flexible connecting line which connects the antenna to the antenna amplifier, for example formed of the material Kapton. A Kapton tape of this type is employed for the signal transmission of signals which are delivered by the antenna to the antenna amplifier. The Kapton tape has a sufficient surface area for the application of components of the matching circuit. In particular, components are arranged at the antenna-side end or the amplifier-side end of the Kapton tape, as the minimum mechanical stresses are applied to these locations. For further protection against environmental influences and/or mechanical damage, e.g. during the fitting of the receiving device, components can be enclosed in a molding compound.

According to a further configuration, it can be provided that the components of the matching circuit are arranged in the form of discrete components in an adapter plug, which is designed to be plugged-in between the antenna amplifier and an antenna terminal of the antenna.

A motor vehicle according to the invention comprises a broadcast receiving device which is configured according to the preceding description. In particular, the carrier of the broadcast receiving device is a window pane, particularly the rear window, of the motor vehicle.

The invention is described in greater detail hereinafter, with reference to the exemplary embodiments represented in the drawings.

### BRIEF DESCRIPTION OF THE DRAWINGS

FIG. 1 shows a schematic representation of a known broadcast receiving device for a motor vehicle.

FIG. 2 shows a schematic representation of a broadcast receiving device according to the invention for a motor vehicle.

### DETAILED DESCRIPTION OF THE DRAWINGS

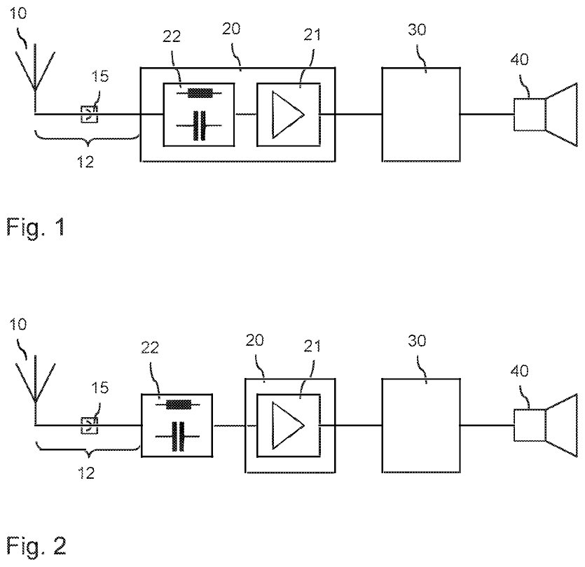

FIG. 1 shows a known broadcast receiving device (in short: receiving device) for a motor vehicle. Broadcast signals are understood to include information of any type, such as e.g. images, sound or text, which can be received by the receiving device 1 by means of electromagnetic waves, and processed.

The receiving device comprises, in a known manner, an antenna 10 having a given antenna impedance, an antenna amplifier 20, a signal processing unit 30 and an output unit 40.

The antenna 10 can assume an arbitrary form. State-of-the-art antennae are customarily configured in the form of window antennae, i.e. the constituent electrical conductors of the antenna are applied to a window pane of the motor vehicle in the form of a wire or an electrically conductive printed layer, or in the form of a foil. Depending upon the type and form of the antenna 10, the latter has a given antenna impedance. The antenna impedance is typically greater than, or substantially greater than 50 ohms.

The antenna amplifier 20 has an amplifier core 21, which executes an amplification of signals received by the antenna. An amplifier impedance of the amplifier core 21 of the antenna amplifier 20 is generally 50 ohms. On the grounds of the mutually differing impedances of the amplifier core 21 and the antenna 10, the antenna amplifier 20 additionally comprises a matching circuit 22. The matching circuit 22 is comprised of passive components, which are generally exclusively coils and capacitors. The matching circuit is designed to match the antenna impedance to the amplifier impedance.

The amplifier core 21 and the matching circuit 22, in a conventional receiving device as represented in FIG. 1, are at least arranged in a common housing of the receiving device, or even share components such as e.g. component carriers (circuit boards or similar). Certification of the antenna amplifier is required for statutory purposes. Certification ensures that the antenna amplifier 20 and the receiving device, as a whole, fulfill statutory requirements.

Each modification to the antenna, e.g. associated with the modified form of the window pane in a different vehicle type, entails a modification to the antenna impedance. As a result, in turn, it is necessary to modify the matching circuit 22, in order to match the modified antenna impedance to the amplifier impedance. This requires a further certification of the antenna amplifier 20. Moreover, for each antenna type or vehicle type, it is necessary to keep an appropriate antenna amplifier in stock. This is associated with a substantial expenditure of costs and time. Additionally, this requires complex logistics.

Depending upon the type of signals which are to be received and processed by the receiving device, the signal processing unit 30 can be e.g. a radio receiver, and the output unit 40 can be a loudspeaker. If the signals, in addition to sound data, also contain images, the signal processing unit 30, alternatively or additionally, can be configured for the processing of images, i.e. the signal processing unit is a TV receiver. Alternatively or additionally, the output unit 40 then comprises a display.

FIG. 2 shows an improved receiving device 1 according to an embodiment of the invention for a motor vehicle. The receiving device differs from the receiving device described in FIG. 1, in that the matching circuit 22 is arranged externally to the amplifier core 21 of the antenna amplifier 20. Specifically, the matching circuit 22 is arranged externally to a housing of the amplifier core 21, and thus of the antenna amplifier 20. As a result, independently of the type and design of the antenna 10 employed in the receiving device, the same antenna amplifier 20, having an amplifier core 21 which is comprised of identical components, can be employed in all cases. Matching of the antenna impedance to the amplifier impedance or to the impedance of the amplifier core 21 is then executed by means of a matching circuit 22 which is individually configured for this combination, externally to the amplifier core.

The matching circuit 22 can be an integral constituent of a signal transmission structure 12, which connects the antenna 10 to the antenna amplifier 20 or to the amplifier core 21. The signal transmission structure 12 comprises the totality of lines, and any antenna terminals 15, which are present between the antenna 10 and the amplifier core 21.

As the matching circuit 22 comprises passive components only, and particularly is comprised exclusively of coils and capacitors, the former can be provided in a variety of ways. The matching circuit can be produced e.g. in the form of a structure on a carrier, by the screen printing of a conductive material having a specific conductivity. To this end, for example, meander-shaped turns and parallel structures can be printed. A conductive silver paste can be employed, for example, as a conductive material. The carrier is particularly a window pane, e.g. the rear window of the motor vehicle, or can be comprised of further constituent elements of the existing antenna terminal 15, e.g. the Kapton tape.

The matching circuit can also be produced using film technology. The film technology is provided, for example, in the form of a conductive foil, which comprises a carrier and a metal film which is applied thereto. A conductive foil of this type can be provided on or between two glass layers of a window pane of the motor vehicle. The metal foil can be processed by means of a laser, in order to generate the desired structure for the constitution of the passive components. By the subtractive ablation of selective regions of the metal foil, specific electrical properties can be achieved, which then constitute the matching circuit.

The matching circuit can also be realized by discrete components. Discrete components can be configured, for example, in the form of SMD (surface mounting device) components. These can be applied, for example, to the window pane onto which the antenna is applied, or to a carrier which is separate from the latter.

Alternatively, the discrete components can be arranged in an adapter plug (not represented in FIG. 2), which is plugged-in between the antenna amplifier 20 and an antenna terminal 15. The discrete components can also be integrated in the antenna terminal 15.

A preferred configuration provides for the application of the discrete components to a Kapton tape which connects the antenna 10 or the antenna terminal 15 to the antenna amplifier 20 or the amplifier core 21. The Kapton tape is thus a constituent of the signal transmission structure 12, or entirely constitutes the signal transmission structure 12. In order to expose the discrete components to the least possible mechanical stress, it is appropriate that the latter should be arranged at an antenna-side end (i.e. at or in the vicinity of the antenna terminal 15) or at the amplifier-side end of the Kapton tape. In these regions, the Kapton tape undergoes the smallest mechanical flexions, such that the connections of the components and the conductor structures of the Kapton tape are not exposed to high mechanical loads. By way of further protection against environmental influences or mechanical effects, components can optionally be enclosed in a molding compound upon assembly.

In conclusion, a broadcast receiving device for a motor vehicle can be provided which, independently of the number of different types, is associated with limited complexity with respect to certification, costs and logistics.

### LIST OF REFERENCE NUMBERS

10 Antenna
12 Signal transmission structure
15 Antenna terminal
20 Amplifier
21 Amplifier core
22 Matching circuit
30 Signal processing unit, e.g. radio receiver or TV receiver
40 Output unit, e.g. loudspeaker

1.-13. (canceled)

14. A broadcast receiving device for a motor vehicle, comprising:
at least one antenna having a given antenna impedance;
an antenna amplifier having an amplifier core and a given amplifier impedance; and
a matching circuit which is configured to adapt the antenna impedance to the amplifier impedance, wherein
the matching circuit is arranged externally to the amplifier core of the antenna amplifier.

15. The broadcast receiving device according to claim 14, wherein
the amplifier core is arranged in a housing.

16. The broadcast receiving device according to claim 14, wherein
the matching circuit is an integral constituent of a signal transmission structure, which signal transmission structure connects the antenna to the antenna amplifier or to the amplifier core.

17. The broadcast receiving device according to claim 14, wherein
the matching circuit is arranged on or in a carrier, on or in which the antenna is provided.

18. The broadcast receiving device according to claim 17, wherein
components of the matching circuit are printed onto the carrier using a conductive material of a specific conductivity.

19. The broadcast receiving device according to claim 17, wherein
components of the matching circuit are produced from a conductive foil by a subtractive process, wherein the foil is flush-bonded to the carrier.

20. The broadcast receiving device according to claim 17, wherein
components of the matching circuit are applied to the carrier in the form of discrete, soldered, components.

21. The broadcast receiving device according to claim 14, wherein
components of the matching circuit are applied in the form of discrete components to a Kapton tape, which Kapton tape connects the antenna to the antenna amplifier.

22. The broadcast receiving device according to claim 21, wherein
the components are arranged at an antenna-side end or at an amplifier-side end of the Kapton tape.

23. The broadcast receiving device according to claim 21, wherein
the components are enclosed in a molding compound.

24. The broadcast receiving device according to claim 14, wherein
components of the matching circuit are arranged in the form of discrete components in an adapter plug, which adapter plug is configured to be plugged-in between the antenna amplifier and an antenna terminal.

25. A motor vehicle comprising a broadcast receiving device according to claim 17.

26. The motor vehicle according to claim 25, wherein
the carrier of the receiving device is a window pane.

27. The motor vehicle according to claim 26, wherein
the carrier is a rear window pain.

28. The motor vehicle according to claim 25, wherein
the carrier is a stranded antenna conductor in a spoiler or a foil arranged behind non-conductive trim parts of the vehicle.
